(19) United States
(12) Patent Application Publication
(10) Pub. No.: US 2020/0388473 A1
(43) Pub. Date: Dec. 10, 2020

(54) PLASMA ELECTRIC FIELD MONITOR, PLASMA PROCESSING APPARATUS AND PLASMA PROCESSING METHOD

(71) Applicant: TOKYO ELECTRON LIMITED, Tokyo (JP)

(72) Inventors: Taro IKEDA, Nirasaki City (JP); Eiki KAMATA, Nirasaki City (JP)

(21) Appl. No.: 16/894,293

(22) Filed: Jun. 5, 2020

(30) Foreign Application Priority Data
Jun. 7, 2019 (JP) 2019-106789

(51) Int. Cl. H01J 37/32; H01L 21/3065; H01L 21/66; H01L 21/67; H01Q 9/30

(52) U.S. Cl. CPC H01J 37/32935; H01J 37/3222; H01L 21/3065; H01L 22/26; H01J 2237/24507; H01L 21/67069; H01Q 9/30; H01J 2237/334; H01L 21/67253

(57) ABSTRACT

There is provided a plasma electric field monitor that monitors an electric field intensity of a wave in a plasma processing apparatus for forming a plasma inside a chamber in which a substrate is accommodated and processing the substrate with the plasma, the plasma having the wave on a surface thereof and existing near an inner wall surface of the chamber, including: at least one monopole antenna provided to extend inward of the chamber from a wall portion of the chamber and perpendicular to the inner wall surface of the chamber, and configured to receive the wave formed on the surface of the plasma; and a coaxial line configured to extract a signal of the electric field intensity of the wave received by the at least one monopole antenna.

### CROSS-REFERENCE TO RELATED APPLICATION

This application is based upon and claims the benefit of priority from Japanese Patent Application No. 2019-106789, filed on Jun. 7, 2019, the entire contents of which are incorporated herein by reference.

### TECHNICAL FIELD

The present disclosure relates to a plasma electric field monitor, a plasma processing apparatus and a plasma processing method.

### BACKGROUND

In a semiconductor device manufacturing process, a plasma process is widely used when performing an etching process, a film forming process and the like on a semiconductor substrate. In recent years, as a plasma processing apparatus for performing such a plasma process, a microwave plasma processing apparatus capable of uniformly forming plasma of high density and low electron temperature has been receiving a lot of attention.

Patent Document 1 describes an RLSA (a registered trademark) microwave plasma processing apparatus as a microwave processing apparatus. The RLSA (a registered trademark) microwave plasma processing apparatus is provided with a planar slot antenna having a number of slots formed in a predetermined pattern at an upper portion of a chamber. Microwaves introduced from a microwave source are radiated through the slots of the planar slot antenna. Then, the radiated microwaves are radiated into a chamber kept at a vacuum through a microwave transmission window, which is made of a dielectric material and is provided below the planar slot antenna. By a microwave electric field generated at this time, a surface wave plasma is formed by a gas introduced into the chamber so that a semiconductor wafer is processed.

### PRIOR ART DOCUMENTS

### Patent Document

Patent Document 1: Japanese laid-open publication No. 2000-294550

### SUMMARY

According to an embodiment of the present disclosure, there is provided a plasma electric field monitor that monitors an electric field intensity of a wave in a plasma processing apparatus for forming a plasma inside a chamber in which a substrate is accommodated and processing the substrate with the plasma, the plasma having the wave on a surface thereof and existing near an inner wall surface of the chamber, including: at least one monopole antenna provided to extend inward of the chamber from a wall portion of the chamber and perpendicular to the inner wall surface of the chamber, and configured to receive the wave formed on the surface of the plasma; and a coaxial line configured to extract a signal of the electric field intensity of the wave received by the at least one monopole antenna.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view showing a schematic configuration of a plasma processing apparatus equipped with a plasma electric field monitor according to an embodiment.

FIG. 2 is a block diagram showing a configuration of a plasma source used in the plasma processing apparatus of FIG. 1.

FIG. 3 is a plan view schematically showing a microwave supply part in the plasma source.

FIG. 4 is a longitudinal cross-sectional view showing a microwave radiation mechanism in the plasma source.

FIG. 5 is a cross-sectional view showing a power feeding mechanism of the microwave radiation mechanism.

FIG. 6 is a cross-sectional view showing a schematic configuration of a plasma electric field monitor.

FIG. 7 is a schematic view showing a state in which a monopole antenna receives a surface wave of plasma.

FIG. 8 is a graph showing a relationship between plasma density (electron density) and the wavelength of the surface wave.

FIG. 9 is a cross-sectional view showing an example in which a concave portion is formed in a chamber wall portion and a monopole antenna is installed so as to protrude from the concave portion.

FIG. 10 is a cross-sectional view showing an example in which a dielectric cover is collectively provided on a plurality of monopole antennas.

FIG. 11 is a cross-sectional view showing an example in which a dielectric cap is provided on each monopole antenna.

FIG. 12 is a cross-sectional view showing an example in which a concave portion is provided in a chamber wall portion, a monopole antenna is installed so as to protrude from the concave portion, and a dielectric member is embedded in the concave portion.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Configuration of Plasma Processing Apparatus>

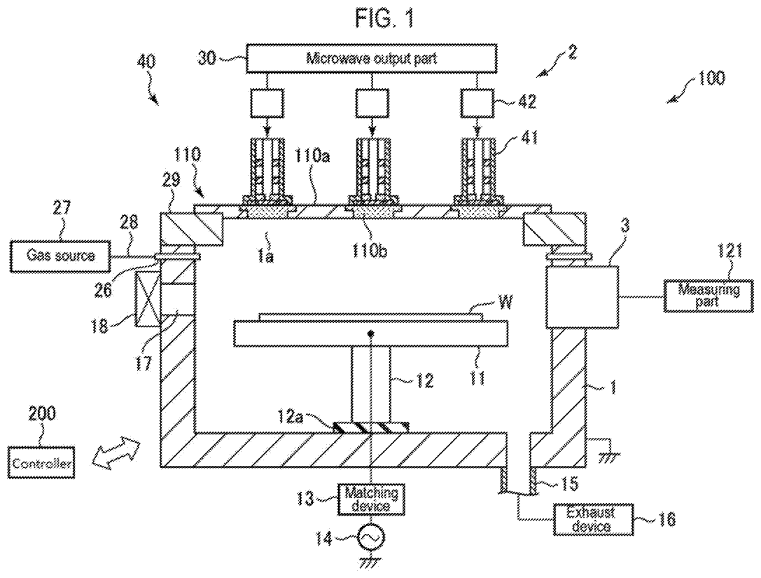

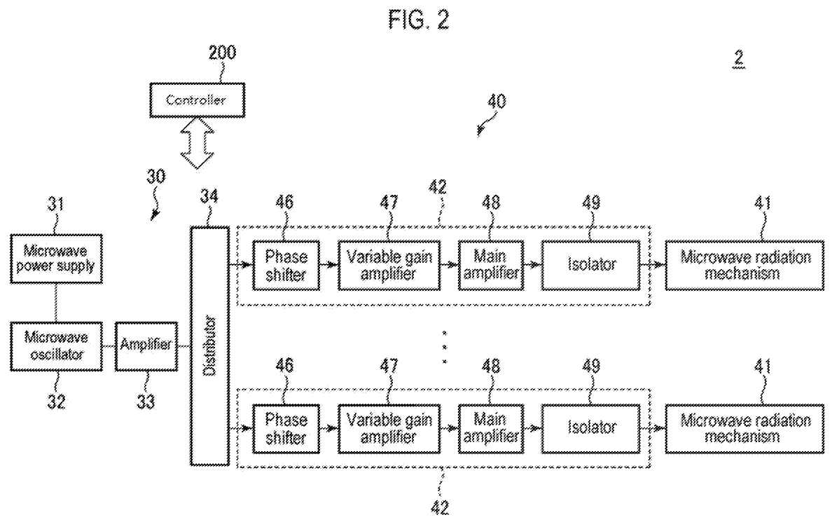

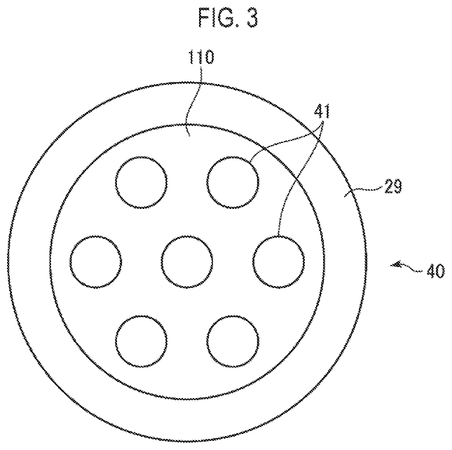

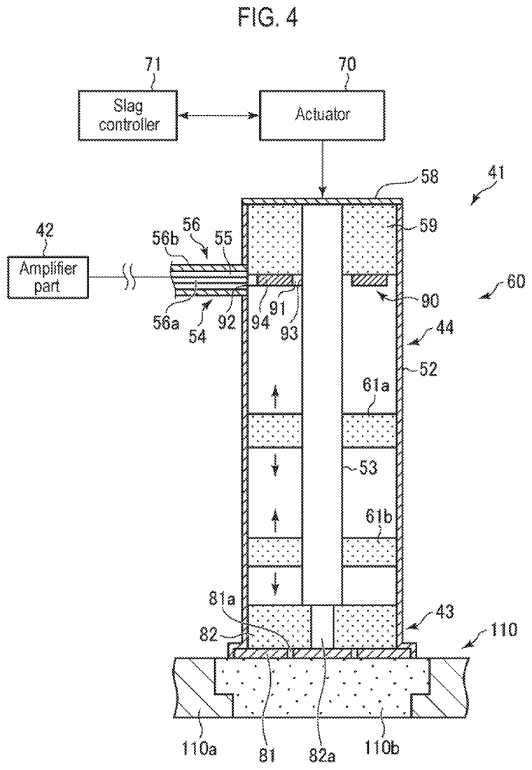

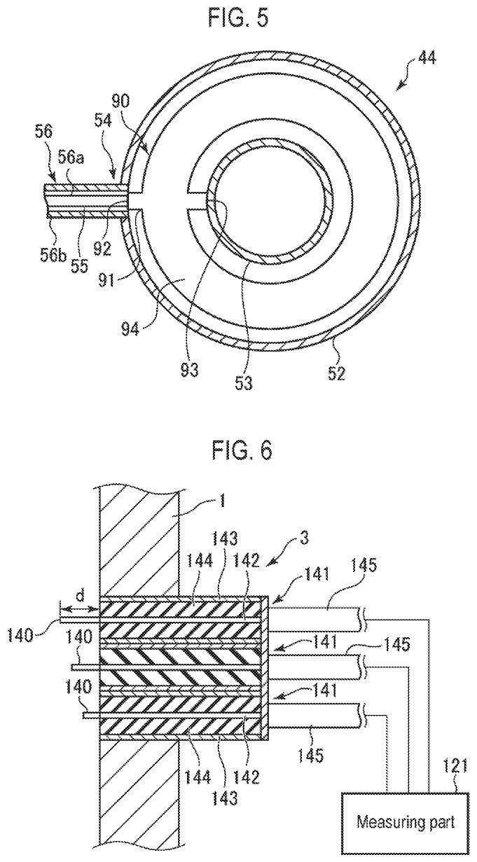

FIG. 1 is a cross-sectional view showing a schematic configuration of a plasma processing apparatus equipped with a plasma electric field monitor according to an embodiment. FIG. 2 is a block diagram showing a configuration of a plasma source used in the plasma processing apparatus of FIG. 1. FIG. 3 is a plan view schematically showing a microwave supply part in the plasma source. FIG. 4 is a longitudinal cross-sectional view showing a microwave radiation mechanism in the plasma source. FIG. 5 is a transverse cross-sectional view showing a power feeding mechanism of the microwave radiation mechanism.

A plasma processing apparatus 10 is configured as plasma etching apparatus for performing, for example, an etching process as a plasma process on a semiconductor wafer (W) (hereinafter referred to as a wafer W) which is a substrate, and performs a plasma process using surface wave plasma. The plasma processing apparatus 100 includes a grounded airtight chamber 1 having a substantially cylindrical shape and made of a metallic material such as aluminum or stainless steel, a plasma source 2 for forming the surface wave plasma inside the chamber 1, and a plasma electric field monitor 3. An opening portion 1a is formed in an upper portion of the chamber 1. The plasma source 2 is provided so as to face the interior of the chamber 1 from the opening portion 1a.

A susceptor 11, which is a support member for horizontally supporting the wafer W, is provided inside the chamber 1 while being supported by a cylindrical support member 12 installed upright at the center of the bottom of the chamber 1 via an insulating member 12a. Examples of the material forming the susceptor 11 and the support member 12 may include aluminum whose surface is anodized.

Although not shown, the susceptor 11 includes an electrostatic chuck for electrostatically attracting the wafer W, a temperature control mechanism, a gas flow path for supplying a heat transfer gas to the back surface of the wafer W, elevating pins that vertically move to transfer the wafer W, and the like. Further, a high frequency bias power supply 14 is electrically connected to the susceptor 11 via a matching device 13. By supplying high frequency power from the high frequency bias power supply 14 to the susceptor 11, ions in plasma are drawn into the wafer W.

An exhaust pipe 15 is connected to the bottom of the chamber 1. An exhaust device 16 including a vacuum pump is connected to the exhaust pipe 15. By operating the exhaust device 16, a gas in the chamber 1 is discharged, thereby allowing an internal pressure of the chamber 1 to be reduced to a predetermined degree of vacuum at a high speed. In addition, a loading/unloading port 17 for loading/unloading the wafer W therethrough and a gate valve 18 for opening/closing the loading/unloading port 17 are provided in a sidewall of the chamber 1.

A ring-shaped gas introduction member 26 is provided along the wall of the chamber 1 at the upper portion of the chamber 1. A large number of gas discharge holes are formed in the inner periphery of the gas introduction member 26. A gas source 27 that supplies a gas such as a plasma generating gas, a processing gas or the like is connected to the gas introduction member 26 via a pipe 28. A noble gas such as an Ar gas or the like may be suitably used as the plasma generating gas. Further, an etching gas usually used for an etching process, for example, a Cl₂ gas or the like, may be used as the processing gas.

The plasma generating gas introduced into the chamber 1 from the gas introduction member 26 is formed into a plasma by microwaves introduced into the chamber 1 from the plasma source 2. Thereafter, when the processing gas is introduced from the gas introducing member 26, the processing gas is excited by the plasma of the plasma generating gas and is formed into a plasma. The wafer W is subjected to a plasma process by the plasma of the processing gas.

### <Plasma Source>

Next, the plasma source 2 will be described. The plasma source 2 is provided for forming surface wave plasma inside the chamber 1 and has a circular top plate 110 supported by a support ring 29 provided on the upper portion of the chamber 1. An airtight seal is provided between the support ring 29 and the top plate 110. As shown in FIG. 2, the plasma source 2 includes a microwave output part 30 for distributing and outputting microwaves to a plurality of paths, and a microwave supply part 40 for transmitting the microwaves output from the microwave output part 30 and radiating them into the chamber 1.

The microwave output part 30 includes a microwave power supply 31, a microwave oscillator 32, an amplifier 33 for amplifying the oscillated microwave, and a distributor 34 for distributing the amplified microwaves to the plurality of paths.

The microwave oscillator 32 oscillates microwaves having a predetermined frequency (for example, 915 MHz) by, for example, a PLL (phase locked loop). The distributor 34 distributes the microwaves amplified by the amplifier 33 while maintaining an impedance matching between the input side and the output side such that the loss of the microwaves occurs as little as possible. In addition to 915 MHz, a desired frequency ranging from 700 MHz to 3 GHz may be used as the frequency of the microwave.

The microwave supply part 40 includes a plurality of amplifying parts 42 that mainly amplify the microwaves distributed by the distributor 34, and microwave radiation mechanisms 41 connected respectively to the plurality of amplifying parts 42.

For example, as shown in FIG. 3, a total of seven microwave radiation mechanisms 41 are arranged on the top plate 110 in which six of them are circumferentially arranged and the remaining one is disposed at the center.

The top plate 110 functions as a vacuum seal and a microwave transmission plate. The top plate 110 includes a metallic frame 110a and microwave transmission windows 110b made of a dielectric material such as quartz. The microwave transmission windows 110b are fitted to the frame 110a and are provided to correspond to portions where the microwave radiation mechanisms 41 are respectively arranged.

Each of the amplifying parts 42 includes a phase shifter 46, a variable gain amplifier 47, a main amplifier 48 constituting a solid state amplifier, and an isolator 49.

The phase shifter 46 is configured to be able to change a phase of the microwave. The phase shifter 46 can modulate the radiation characteristics by adjusting the phase. For example, the phase shifter 46 can change the plasma distribution by adjusting the phase of each amplifying part 42 to control directionality, or can obtain a circularly polarized wave by shifting the phase by 90 degrees in adjacent amplifying parts 42. Further, the phase shifter 46 can be used for the purpose of spatial synthesis in a tuner by adjusting the delay characteristic between components in the amplifier. However, in a case in which it is not necessary to modulate the radiation characteristic or adjust the delay characteristic between components in the amplifier, the phase shifter 46 may be omitted.

The variable gain amplifier 47 is an amplifier for adjusting the power level of microwaves input to the main amplifier 48 to adjust the deviation of individual antenna modules or adjust the plasma intensity. By changing the variable gain amplifier 47 for each amplifying part 42, a distribution can be generated in the generated plasma.

The main amplifier 48 constituting a solid state amplifier may be configured to include, for example, an input matching circuit, a semiconductor amplifying element, an output matching circuit and a high-Q resonance circuit.

The isolator 49 is provided to isolate reflected microwaves reflected by the microwave radiation mechanism 41 toward the main amplifier 48, and includes a circulator and a dummy load (coaxial terminator). The circulator guides the microwaves reflected by an antenna part 43 (to be described later) of the microwave radiation mechanism 41 to the dummy load, and the dummy load converts the reflected microwaves guided by the circulator into heat.

As shown in FIG. 4, the microwave radiation mechanism 41 includes a waveguide 44 having a coaxial structure to transmit the microwaves, and the antenna part 43 for radiating the microwaves transmitted through the waveguide 44 into the chamber 1. Then, the microwaves radiated from the microwave radiation mechanism 41 into the chamber 1 are synthesized in an internal space of the chamber 1, thereby forming surface wave plasma inside the chamber 1.

The waveguide 44 is configured such that a cylindrical outer conductor 52 and a rod-shaped inner conductor 53 provided at the center thereof are coaxially arranged. The antenna part 43 is provided at the leading end of the waveguide 44. In the waveguide 44, the inner conductor 53 is on the power feeding side, and the outer conductor 52 is on the ground side. Upper ends of the outer conductor 52 and the inner conductor 53 serve as reflection plates 58.

A power feeding mechanism 54 for feeding the microwaves (electromagnetic waves) is provided on the base end side of the waveguide 44. The power feeding mechanism 54 has a microwave power introduction port 55 provided on a side surface of the waveguide 44 (the outer conductor 52) to introduce microwave power. As a power feed line for supplying the microwaves amplified by the amplifying part 42 therethrough, a coaxial line 56 including an inner conductor 56a and an outer conductor 56b is connected to the microwave power introduction port 55. A power feeding antenna 90 extending horizontally toward the interior of the outer conductor 52 is connected to the leading end of the inner conductor 56a of the coaxial line 56.

The power feeding antenna 90 is formed by, for example, cutting out a metal plate of aluminum or the like and then setting the same in a mold of a dielectric member such as Teflon (a registered trademark). A slow-wave member 59 made of a dielectric material is interposed between the reflection plate 58 and the power feeding antenna 90. When microwaves having a high frequency such as 2.45 GHz is used, the slow-wave member 59 may be omitted. By reflecting an electromagnetic wave radiated from the power feeding antenna 90 by the reflection plate 58, the maximum electromagnetic wave is transmitted into the waveguide 44 having the coaxial structure. In that case, it is preferable to set the distance from the power feeding antenna 90 to the reflection plate 58 to be about half-wavelength of λg/4. However, in microwaves having a low frequency, such a configuration may not be directly applicable due to constraints in the radial direction. In that case, it is preferable to optimize the shape of the power feeding antenna so that the antinode of the electromagnetic wave generated from the power feeding antenna 90 is induced below the power feeding antenna 90, rather than toward the power feeding antenna 90.

As shown in FIG. 5, the power feeding antenna 90 is connected to the inner conductor 56a of the coaxial line 56 in the microwave power introduction port 55. The power feeding antenna 90 includes an antenna main body 91 having a first pole 92 to which an electromagnetic wave is supplied and a second pole 93 from which the supplied electromagnetic wave is radiated, and a ring-shaped reflection part 94 extending from both sides of the antenna main body 91 along the outside of the inner conductor 53. An electromagnetic wave incident on the antenna main body 91 and an electromagnetic wave reflected by the reflection part 94 form a standing wave. The second pole 93 of the antenna main body 91 is in contact with the inner conductor 53.

The microwave power is fed into the space between the outer conductor 52 and the inner conductor 53 by the microwaves (the electromagnetic waves) emitted from the power feeding antenna 90. Then, the microwave power supplied to the power feeding mechanism 54 propagates toward the antenna part 43.

A tuner 60 is provided in the waveguide 44. The tuner 60 has two slags 61a and 61b provided between the outer conductor 52 and the inner conductor 53, and an actuator 70 for driving the slags provided outside of (above) the reflection plate 58. The tuner 60 drives the two slags 61a and 61b independently to match the impedance of the load (plasma) inside the chamber 1 with the characteristic impedance of the microwave power supply in the microwave output part 30. For example, two slag moving shafts (not shown) made of screw rods are provided in the inner space of the inner conductor 53 so as to extend in the longitudinal direction. The actuator 70 has two motors for independently rotating the slag moving shafts. Thus, the slag moving shafts can be separately rotated by the respective motors of the actuator 70, thereby moving up and down the slags 61a and 61b independently of each other.

The positions of the slags 61a and 61b are controlled by a slag controller 71. For example, the slag controller 71 sends a control signal to the motors constituting the actuator 70 based on an impedance value of an input terminal detected by an impedance detector (not shown) and position information of the slags 61a and 61b detected by an encoder or the like. Thus, the positions of the slags 61a and 61b are controlled, and the impedances thereof are adjusted. The slag controller 71 performs impedance matching so that the termination has, for example, 50Ω. When only one of the two slags is moved, a trajectory which passes through the origin of the Smith chart is drawn, and when both are moved simultaneously, only the phase is rotated.

The antenna part 43 includes a planar slot antenna 81 having a planar shape, and a slow-wave member 82 provided on the back surface (upper surface) of the planar slot antenna 81. A cylindrical member 82a made of a conductor and connected to the inner conductor 53 penetrates the center of the slow-wave member 82, and is connected to the planar slot antenna 81. The slow-wave member 82 and the planar slot antenna 81 have a disc shape with a larger diameter than that of the outer conductor 52. A lower end of the outer conductor 52 extends to the planar slot antenna 81. The periphery of the slow-wave member 82 is covered with the outer conductor 52.

The planar slot antenna 81 has slots 81a for radiating the microwaves therethrough. The number, arrangement and shape of the slots 81a may be appropriately set so as to efficiently emit the microwaves. A dielectric material may be inserted into each slot 81a.

The slow-wave member 82 has a dielectric constant higher than that of vacuum and is made of, for example, quartz, ceramics, a fluorinated-based resin such as polytetrafluoroethylene or the like, or a polyimide-based resin. The slow-wave member 82 has a function of shortening the antenna by making the wavelength of the microwaves shorter than that in a vacuum. The phase of the microwaves can be adjusted by the thickness of the slow-wave member 82. The thickness of the slow-wave member 82 is adjusted so that the planar slot antenna 81 becomes the “antinode” of the standing wave. Thus, the reflection can be minimized and the radiant energy of the planar slot antenna 81 can be maximized.

The microwave transmission window 110b of the top plate 110 is disposed on the leading end side of the planar slot antenna 81. Then, the microwaves amplified by the main amplifier 48 pass between peripheral walls of the inner conductor 53 and the outer conductor 52, pass through the microwave transmission window 110b via the planar slot antenna 81, and are radiated into the internal space of the chamber 1. The microwave transmission window 110b may be made of the same dielectric material as the slow-wave member 82.

In the present embodiment, the main amplifier 48, the tuner 60 and the planar slot antenna 81 are arranged close to each other. The tuner 60 and the planar slot antenna 81 constitute a lumped constant circuit existing within a half-wavelength. Further, a combined resistance of the planar slot antenna 81, the slow-wave member 82 and the microwave transmission window 110b is set to 50Ω. To do this, the tuner 60 directly tunes the plasma load, thereby efficiently transmitting energy to the plasma.

Each component of the plasma processing apparatus 100 is controlled by a controller 200 having a microprocessor. The controller 200 includes a storage part that stores a process sequence of the plasma processing apparatus 100, and a process recipe as a control parameter, an input means, a display and the like, and controls the plasma processing apparatus 100 according to the selected process recipe.

### <Plasma Electric Field Monitor>

Next, the plasma electric field monitor 3 will be described. FIG. 6 is a cross-sectional view showing a schematic configuration of the plasma electric field monitor 3. The plasma electric field monitor 3 monitors an electric field of a surface wave formed near the inner wall surface by the plasma in the chamber 1, and has a monopole antenna 140 provided on a wall portion (a sidewall in this embodiment) of the chamber 1. A plurality of monopole antennas 140 may be provided as shown in FIG. 6.

The monopole antenna 140 is made of a conductor such as aluminum and is provided so as to extend inward of the chamber 1 from the wall portion of the chamber 1 and be perpendicular to the inner wall surface of the chamber 1.

The plasma electric field monitor 3 has coaxial lines 141 connected to the monopole antennas 140, which extend outward of the chamber 1 and extract signals received by the respective monopole antennas 140. The coaxial line 141 has an inner conductor 142 connected to the monopole antenna 140, and an outer conductor 143 provided on the outer periphery of the inner conductor 142. A dielectric member 144 is interposed between the inner conductor 142 and the outer conductor 143. The monopole antenna 140 protrudes into the chamber 1 from the dielectric member 144. The coaxial line 141 is connected to a measuring part 121 via a coaxial cable 145. The coaxial line 141 and the coaxial cable 145 may be integrated to form a single coaxial line.

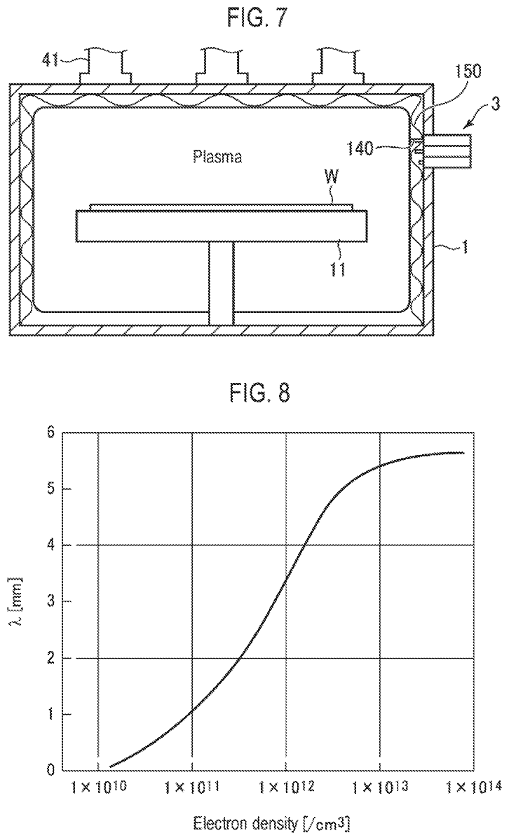

As shown in FIG. 7, the monopole antenna 140 receives a surface wave 150 formed on the plasma surface inside the chamber 1 and existing near the inner wall surface of the chamber 1 as an electric field intensity signal. The received electric field intensity signal of the surface 1I wave 150 is extracted, for example as a current value, by the coaxial line 141, and is monitored. The monitored electric field intensity signal is sent to the measuring part 121 via the coaxial cable 145.

Assuming that the wavelength of surface wave plasma is λ, when the wavelength is (2n−1)×λ/4 (where n is a natural number of one or more), the electric field intensity of the surface wave shows a maximum value. Thus, a length d (see FIG. 6) of the monopole antenna 140 is set to (2n−1)×λ/4. A diameter of the monopole antenna 140 may fall within a range of 2 to 3 mm. A thickness of the surface wave may be about 0.02 to 0.5 mm, and the length of the monopole antenna 140 may be set in consideration of the thickness of the surface wave.

Since the wavelength λ of the surface wave changes depending on the plasma density (electron density), the plurality of monopole antennas 140 may be provided as described above so as to cope with a change in the plasma density (electron density) due to a change in process conditions and the lengths thereof may be set to be different from each another. However, when the plasma conditions are almost constant, a single monopole antenna 140 may be used.

The relationship between the wavelength of the surface wave plasma and the plasma density can be obtained from the following equation (1) derived from Maxwell's equation.

εᵣ·(α/β)tan h(αs)+1=0 (1)

where, εᵣ is the relative permittivity of the sheath of the surface wave plasma, α is the wave number in the sheath, β is the wave number in the plasma main body, and s is the thickness of the sheath.

FIG. 8 shows a relationship between the wavelength of the surface wave plasma and the plasma density (electron density) obtained from the above equation (1). When a frequency range of the microwaves is 500 to 2,450 MHz, which is usually used in the plasma processing apparatus 100 of FIG. 1, the wavelength k is calculated as about 2 to 4 mm based on the plasma density obtained by experiment and the relationship of FIG. 8. Therefore, when it is desired to set the length d of the monopole antenna 140 to λ/4 (in the above (2n−1)×λ/4 and n=1), the length d is in the range of about 0.5 to 1 mm. Therefore, in the case where the plurality of monopole antennas 140 are provided, it is preferable to change the length d in the range of 0.5 to 1 mm. Of course, when n=2 or more, the length d of the monopole antenna 140 is set to be a value corresponding to n=2 or more.

During the plasma processing in the chamber 1, the plasma electric field monitor 3 receives the surface wave of the surface wave plasma by the monopole antenna 140. The electric field intensity of the received surface wave is directly monitored by extracting it, for example, as a current value in the coaxial line 141. The monitor signal is sent to the measuring part 121 via the coaxial cable 145. In the measuring part 121, a threshold corresponding to an electric field intensity (for example, 0.5 MV/cm) obtained in consideration of a specific safety factor (for example, 200%) with respect to an electric field intensity (for example, 1 MV/cm) of the surface wave in which abnormal discharge occurs, which is determined in advance by experiment, is set as a threshold at which abnormal discharge may occur. Then, it is determined whether or not a signal of the electric field intensity monitored by the measuring part 121 exceeds the threshold.

As described above, since the electric field intensity has a maximum value at (2n−1)×λ/4, for example, λ/4, the signal monitored via the monopole antenna 140 having the corresponding length corresponds to the highest electric field value. Therefore, it is possible to determine a possibility of the occurrence of abnormal discharge with high accuracy based on the signal monitored by the plasma electric field monitor 3.

When the monitored signal exceeds the threshold, a signal indicating that the monitored signal has exceeded the threshold is output from the measuring part 121 to the controller 200. Upon receiving this signal, the controller 200 performs control for avoiding an abnormal discharge, such as changing the process conditions (such as decreasing the microwave power), issuing an alarm, stopping the apparatus or the like.

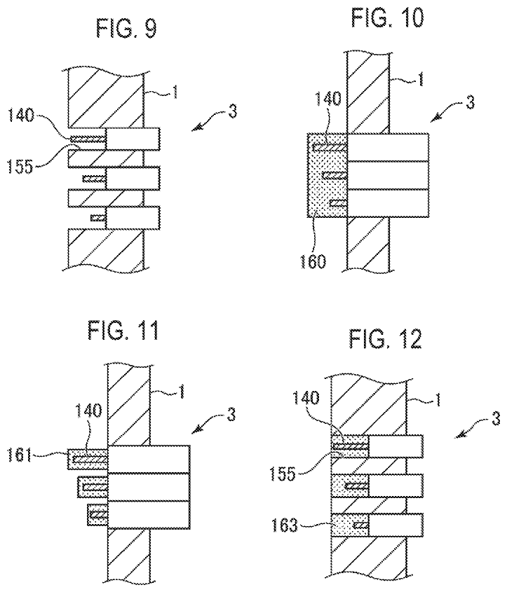

In the example of FIG. 6, since the monopole antennas 140 are exposed in a state where they protrude into the plasma space in the chamber 1, an abnormal discharge may occur near the monopole antennas 140. From the viewpoint of preventing such a situation, as shown in FIG. 9, a concave portion 155 having a size that allows a surface wave to enter the inner wall surface of the chamber 1 is provided. Each monopole antenna 140 may be provided so as to protrude vertically from a bottom surface of the concave portion 155 and so as not to protrude beyond the peripheral surface of the inner wall of the chamber 1. In some embodiments, as shown in FIGS. 10 and 11, each monopole antenna 140 may be covered with a dielectric material. FIG. 10 shows an example in which the plurality of monopole antennas 140 are collectively covered with one dielectric cover 160, and FIG. 11 shows an example in which a dielectric cap 161 is provided for each monopole antenna 140. When a dielectric material is used, the wavelength of the surface wave becomes an effective wavelength kg. In addition, as shown in FIG. 12, a dielectric member 163 may be embedded in the concave portion 155 in which each monopole antenna 140 protrudes.

### <Operation of Plasma Processing Apparatus>

Next, the operation of the plasma processing apparatus 100 configured as above will be described. First, a wafer W is loaded into the chamber 1 and placed on the susceptor 11. Then, while a plasma-generating gas, for example, an Ar gas, is introduced from the gas source 27 into the chamber 1 via the pipe 28 and the gas introduction member 26, microwaves are introduced from the plasma source 2 into the chamber 1 to form plasma. The plasma formed at this time becomes surface wave plasma.

After the plasma is formed, a processing gas, for example, an etching gas such as a Cl₂ gas, is discharged from the processing gas source 27 into the chamber 1 via the pipe 28 and the gas introduction member 26. The discharged processing gas is excited by the plasma of the plasma-generating gas and is converted to plasma. The wafer W is subjected to a plasma process, for example, an etching process, by the plasma of the processing gas.

In generating the plasma, in the plasma source 2, the microwave power oscillated from the microwave oscillator 32 of the microwave output part 30 is amplified by the amplifier 33 and then is distributed into a plurality of paths by the distributor 34. Thereafter, the distributed microwave powers are guided to the microwave supply part 40. In the microwave supply part 40, the microwave powers distributed into the plurality of paths in the above manner are individually amplified by the respective main amplifiers 48 constituting solid state amplifiers and are respectively fed to the waveguides 44 of the microwave radiation mechanisms 41. In each microwave radiation mechanism 41, the impedance is automatically matched by the tuner 60, and thus in a state where power reflection is not substantially present, the microwaves are radiated and spatially synthesized into the chamber 1 via the slots 81a of the planar slot antenna 81 of the antenna part 43 and the microwave transmission window 110b.

The feeding of the power to the waveguide 44 of the microwave radiation mechanism 41 is performed from the side surface of the waveguide 44 via the coaxial line 56. That is, the microwaves (electromagnetic waves) propagating from the coaxial line 56 are fed to the waveguide 44 from the microwave power introduction port 55 provided on the side surface of the waveguide 44. When the microwaves (electromagnetic waves) reach the first pole 92 of the power feeding antenna 90, the microwaves (electromagnetic waves) propagate along the antenna main body 91 and are radiated from the second pole 93 which is the leading end of the antenna main body 91. In addition, the microwaves (electromagnetic waves) propagating on the antenna main body 91 are reflected by the reflection part 94 and are combined with incident waves to generate standing waves. When the standing waves are generated at a position where the power feeding antenna 90 is disposed, an induced magnetic field is generated along the outer wall of the inner conductor 53, and an induced electric field is induced by the induced magnetic field. As a result of such linked actions, the microwaves (electromagnetic waves) propagate in the waveguide 44 and are guided to the antenna part 43.

The microwave radiation mechanism 41 is extremely compact because the antenna part 43 and the tuner 60 are integrated. Therefore, the surface wave plasma source 2 itself can be made compact. Further, the main amplifier 48, the tuner 60 and the planar slot antenna 81 are provided close to each another. In particular, the tuner 60 and the planar slot antenna 81 can be configured as a lumped constant circuit. Further, by setting the combined resistance of the planar slot antenna 81, the slow-wave member 82 and the microwave transmission window 110b to 50Ω, the plasma load can be tuned by the tuner 60 with high accuracy. In addition, the tuner 60 is configured as a slag tuner that can perform the impedance matching by moving the two slags 61a and 61b. Thus, the tuner 60 has a compact and low-loss configuration. Further, since the tuner 60 and the planar slot antenna 81 are arranged close to each other to constitute a lumped constant circuit and function as a resonator, the impedance mismatch which may occur over an extent to the planar slot antenna 81, can be eliminated with high accuracy. Further, the mismatched portion can be substantially used as a plasma space. Thus, plasma control with high precision is possible by the tuner 60.

By the way, in the plasma processing apparatus using the microwaves as in the present embodiment, an abnormal discharge may occur depending on process conditions when large power is used. The abnormal discharge is often an arc-shaped discharge. Once the abnormal discharge occurs, the interior of the chamber is contaminated by chamber surface members and suffers from enormous damage.

In order to prevent such abnormal discharge beforehand, it is conceivable to directly measure the electric field intensity near the inner wall surface of the chamber 1, but such a method has not been found so far.

As a result of studies by the inventors, it has been founded that in the case of the surface wave plasma in which the surface waves exist near the inner wall surface of the chamber 1 as in the present embodiment, the electric field intensity of the surface waves can be monitored by installing the monopole antennas 140 extending inward of the chamber 1 to receive signals of the surface waves.

That is, in the present embodiment, the plasma electric field monitor 3 is provided to receive the surface waves by the monopole antennas 140, which are provided so as to extend from the wall portion of the chamber 1 toward the interior of the chamber 1 and be perpendicular to the inner wall surface of the chamber 1, and to directly monitor the electric field intensity of the surface waves by the coaxial lines 141. As a result, the monopole antennas 140 receive the surface waves 150 as signals of the electromagnetic field intensity. The signals are extracted via the coaxial lines 141 and are monitored.

Thus, the abnormal discharge can be prevented beforehand by performing the plasma process as follows.

First, as described above, the plasma electric field monitor 3 is provided to include the monopole antennas 140 that extend toward the interior of the chamber 1 from the wall portion of the chamber 1 and receive the surface waves, and the coaxial lines 141 that extract the signals of the electric field intensity of the surface waves received by the monopole antennas 140.

Subsequently, the electric field intensity of the surface waves at which the abnormal discharge occurs inside the chamber 1 is determined in advance by experiment or the like. Based on the determined electric field intensity, a threshold at which the abnormal discharge may occur is set in the measuring part 121 in consideration of, for example, a specific safety factor.

Next, a plasma process is performed inside the chamber 1. At the time of the plasma process, the surface waves are received by the monopole antennas 140, and signals of the surface wave electric field intensity are extracted via the coaxial lines 141 and are monitored.

Subsequently, the measuring part 121 determines whether or not the monitored signals of the electric field intensity exceed a threshold. When it is determined that the signals of the electric field intensity exceed the threshold, control is performed to avoid the abnormal discharge. Specifically, control including changing the process conditions (such as decreasing the microwave power or the like), issuing an alarm, or stopping the apparatus is performed.

In the above manner, the abnormal discharge inside the chamber 1 can be prevented beforehand.

At this time, the length d of the monopole antenna 140 is set to (2n−1)×λ/4 (where n is a natural number of one or more) at which the electric field intensity becomes maximum according to the plasma density (electron density). As a result, the signal monitored by the monopole antenna 140 corresponds to the highest electric field value. Therefore, the possibility of occurrence of the abnormal discharge can be determined with high accuracy from the signals monitored by the plasma electric field monitor 3.

The wavelength λ of the surface waves changes depending on the plasma density (electron density). By providing the plurality of monopole antennas 140 having different lengths, it is possible to cope with a change in the plasma density (electron density).

If the monopole antennas 140 are exposed while protruding inward of the chamber 1, the abnormal discharge may occur near the monopole antennas 140. On the other hand, in FIG. 9, the concave portions 155 having a size that allows penetration of the surface waves are formed in the inner wall surface of the chamber 1, and the monopole antennas 140 are provided in the respective concave portions 155 so as not to protrude beyond the peripheral surface of the inner wall of the chamber 1. In FIGS. 10 and 11, the monopole antennas 140 are covered with a dielectric material. This prevents the monopole antennas 140 from being exposed while protruding inward of the plasma space, thereby preventing the abnormal discharge caused by the monopole antennas 140.

Technologies for measuring an electric field intensity of surface waves in a microwave plasma processing apparatus is disclosed in, for example, Japanese laid-open publication No. 2001-203097 and Japanese laid-open publication No. 2013-77441. However, these technologies monitor surface waves propagating through a dielectric material, and are not intended to directly monitor the electric field intensity of the surface waves of the plasma itself.

### <Other Applications>

The embodiments have been described above. However, it should be noted that the embodiments disclosed herein are exemplary in all respects and are not restrictive. The above-described embodiments may be omitted, replaced or modified in various forms without departing from the scope and spirit of the appended claims.

For example, in the above-described embodiments, the plasma source has been described by taking an example of the plurality of microwave radiation mechanisms each including the waveguide having a coaxial structure to transmit the microwaves therethrough, the planar slot antenna, and the microwave transmission window. However, one microwave radiation mechanism may be used.

In the above-described embodiments, the example has been described in which the surface wave plasma is formed inside the chamber 1 and the electric field intensity of the surface waves formed near the inner wall surface is monitored. However, the present disclosure is not limited thereto, and any plasma may be applied as long as the plasma formed inside the chamber is plasma having a wave formed on the surface and the wave is plasma formed near the inner wall surface of the chamber. For example, when a frequency of an applied high frequency power in a capacitively-coupled parallel-plate-type plasma processing apparatus is 100 MHz or more, a sheath wave is formed in a plasma sheath formed near the inner wall surface of the chamber. The electric field intensity of such a sheath wave may be monitored. The capacitively-coupled parallel-plate-type plasma processing apparatus applies the high frequency power between parallel-plate electrodes. When the frequency of the high frequency power at that time is 100 MHz or more, the electromagnetic waves are reflected by the formed plasma so that the electric field is concentrated on the plasma sheath, and the sheath waves are formed in the sheath. Thus, the sheath waves can be received by the monopole antennas.

Further, in the above-described embodiments, the plasma electric field monitor is provided on the sidewall of the chamber. However, the present disclosure is not limited thereto. For example, the plasma electric field monitor may be provided on another wall such as an upper wall of the chamber.

Further, in the above-described embodiments, an apparatus for performing an etching process is exemplified as the plasma processing apparatus. However, the present disclosure is not limited thereto. For example, the plasma process may include another plasma process such as a film forming process, an oxynitride film process or an ashing process. Furthermore, the substrate is not limited to the semiconductor wafer W, but may be another substrate such as an FPD (flat panel display) substrate represented by an LCD (liquid crystal display) substrate, a ceramic substrate or the like.

According to the present disclosure in some embodiments, it is possible to provide a plasma electric field monitor capable of preventing abnormal discharge of plasma inside a chamber beforehand, and a plasma processing apparatus and a plasma processing method using the same.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma electric field monitor that monitors an electric field intensity of a wave in a plasma processing apparatus for forming a plasma inside a chamber in which a substrate is accommodated and processing the substrate with the plasma, the plasma having the wave on a surface thereof and existing near an inner wall surface of the chamber, comprising:
at least one monopole antenna provided to extend inward of the chamber from a wall portion of the chamber and be perpendicular to the inner wall surface of the chamber, and configured to receive the wave formed on the surface of the plasma; and
a coaxial line configured to extract a signal of the electric field intensity of the wave received by the at least one monopole antenna.

2. The plasma electric field monitor of claim 1, wherein the at least one monopole antenna is configured to have a length of (2n−1)×λ/4 (where n is a natural number of one or more and λ is a wavelength of the wave formed on the surface of the plasma).

3. The plasma electric field monitor of claim 2, wherein the at least one plasma electric filed monitor includes a plurality of monopole antennas, and
wherein the wavelength of the wave formed on the surface of the plasma changes depending on a plasma density of the plasma, and the plurality of monopole antennas have different lengths corresponding to (2n−1)×λ/4 in a range of the plasma density used for a plasma process.

4. The plasma electric field monitor of claim 3, wherein when the lengths of the plurality of monopole antennas are set to λ/4, the lengths of the plurality of monopole antennas are in a range of 0.5 to 1 mm.

5. The plasma electric field monitor of claim 4, wherein the at least one monopole antenna is provided so as not to protrude beyond a peripheral surface of an inner wall of the chamber while protruding vertically from a bottom surface of a concave portion provided on the peripheral surface of the inner wall of the chamber.

6. The plasma electric field monitor of claim 5, wherein a dielectric material is embedded in the concave portion.

7. The plasma electric field monitor of claim 6, wherein the plasma is a surface wave plasma formed by guiding microwaves to the chamber through a slot of a planar slot antenna and a microwave transmission window made of a dielectric material,
wherein the wave is a surface wave formed on a surface of the surface wave plasma, and
wherein the at least one monopole antenna receives the surface wave and monitors an electric field intensity of the surface wave.

8. The plasma electric field monitor of claim 1, wherein the at least one monopole antenna is provided so as not to protrude beyond a peripheral surface of an inner wall of the chamber while protruding vertically from a bottom surface of a concave portion provided on the peripheral surface of the inner wall of the chamber.

9. The plasma electric field monitor of claim 1, wherein the at least one monopole antenna is covered with a dielectric material.

10. The plasma electric field monitor of claim 1, wherein the plasma is a surface wave plasma formed by guiding microwaves to the chamber through a slot of a planar slot antenna and a microwave transmission window made of a dielectric material,
wherein the wave is a surface wave formed on a surface of the surface wave plasma, and
wherein the at least one monopole antenna receives the surface wave and monitors an electric field intensity of the surface wave.

11. The plasma electric field monitor of claim 1, wherein the plasma is a capacitively-coupled plasma formed by applying a high frequency power having a frequency of 100 MHz or more between parallel-plate electrodes,
wherein the wave is a sheath wave formed on a plasma sheath of a surface of the capacitively-coupled plasma, and
wherein the at least one monopole antenna receives the sheath wave and monitors the electric field intensity of the sheath wave.

12. A plasma processing apparatus for performing a process on a substrate by a plasma, comprising:
a chamber in which the substrate is accommodated;
a microwave output part configured to output microwaves;
a microwave radiation mechanism provided on a microwave transmission path through which the microwaves outputted from the microwave output part are transmitted, and including a slot antenna having a slot for radiating the microwaves therethrough and a microwave transmission window made of a dielectric material and configured to transmit the microwaves radiated from the slot therethrough; and
a plasma electric field monitor configured to monitor an electric field intensity of a surface wave that exists on a surface of a plasma formed inside the chamber by the microwaves radiated from the microwave radiation mechanism and near an inner wall of the chamber,
wherein the plasma electric field monitor comprises:
at least one monopole antenna provided to extend inward of the chamber from a wall portion of the chamber while protruding perpendicular to a wall surface of the chamber, and configured to receive the surface wave formed on the surface of the plasma; and
a coaxial line configured to extract a signal of the electric field intensity of the surface wave received by the at least one monopole antenna.

13. The plasma processing apparatus of claim 12, wherein the at least one monopole antenna is configured to have a length of (2n−1)×λ/4 (where n is a natural number of one or more and λ is a wavelength of the surface wave formed on the surface of the plasma).

14. The plasma processing apparatus of claim 13, wherein the at least one monopole antenna includes a plurality of monopole antennas, and
wherein the wavelength of the surface wave formed on the surface of the plasma changes depending on a plasma density of the plasma, and the plurality of monopole antennas have different lengths corresponding to (2n−1)×λ/4 in a range of the plasma density used for a plasma process.

15. A plasma processing method of forming a plasma inside a chamber in which a substrate is accommodated, and processing the substrate with the plasma, the plasma having a wave on a surface thereof and existing near an inner wall surface of the chamber, the method comprising:
providing at least one monopole antenna provided perpendicular to an inner wall surface of the chamber while extending inward of the chamber from a wall portion of the chamber, and a coaxial line configured to extract a signal of an electric field intensity of the wave received by the at least one monopole antenna;
setting a threshold at which an abnormal discharge is likely to occur based on an electric field intensity of the wave at which the abnormal discharge occurs inside the chamber, which has been determined in advance;
performing a plasma process inside the chamber,
extracting and monitoring, during the plasma process, the signal of the electric field intensity of the wave received by the at least one monopole antenna via the coaxial line:
determining whether or not the monitored signal of the electric field intensity exceeds the threshold; and
when it is determined that the monitored signal of the electric field intensity exceeds the threshold, performing a control to avoid the abnormal discharge.

16. The method of claim 15, wherein the control performed to avoid the abnormal discharge includes at least one of changing process conditions of the plasma process, issuing an alarm, and stopping a plasma processing apparatus that performs the plasma process.

17. The method of claim 16, wherein the at least one monopole antenna is configured to have a length of (2n−1)×λ/4 (where n is a natural number of one or more and) is a wavelength of the wave formed on the surface of the plasma).

18. The method of claim 17, wherein the at least one plasma electric filed monitor includes a plurality of monopole antennas, and
wherein the wavelength of the wave formed on the surface of the plasma changes depending on a plasma density of the plasma, and the plurality of monopole antennas have different lengths corresponding to (2n−1)×λ/4 in a range of the plasma density used for the plasma process.

19. The method of claim 18, wherein the plasma is a surface wave plasma formed by guiding microwaves to the chamber through a slot of a planar slot antenna and a microwave transmission window made of a dielectric material,
wherein the wave is a surface wave formed on a surface of the surface wave plasma, and
wherein the at least one monopole antenna receives the surface wave and monitors an electric field intensity of the surface wave.

20. The method of claim 15, wherein the plasma is a capacitively-coupled plasma formed by applying a high frequency power having a frequency of 100 MHz or more between parallel-plate electrodes,
wherein the wave is a sheath wave formed on a plasma sheath of a surface of the capacitively-coupled plasma, and
wherein the at least one monopole antenna receives the sheath wave and monitors the electric field intensity of the sheath wave.
